(19) United States
(12) Patent Application Publication
(10) Pub. No.: US 2014/0021616 A1
(43) Pub. Date: Jan. 23, 2014

(54) SEMICONDUCTOR STRUCTURE

(71) Applicants: Diego Anzola, South Burlington, VT (US); Evan G. Colgan, Chestnut Ridge, NY (US); Kevin K. Dezfulian, Mount Kisco, NY (US); Daniel C. Edelstein, White Plains, NY (US); Mark C. H. Lamorey, South Burlington, VT (US); Sampath Purushothaman, Yorktown Heights, NY (US); Thomas M. Shaw, Peekskill, NY (US); Roy R. Yu, Poughkeepsie, NY (US)

(72) Inventors: Diego Anzola, South Burlington, VT (US); Evan G. Colgan, Chestnut Ridge, NY (US); Kevin K. Dezfulian, Mount Kisco, NY (US); Daniel C. Edelstein, White Plains, NY (US); Mark C. H. Lamorey, South Burlington, VT (US); Sampath Purushothaman, Yorktown Heights, NY (US); Thomas M. Shaw, Peekskill, NY (US); Roy R. Yu, Poughkeepsie, NY (US)

(73) Assignee: INTERNATIONAL BUSINESS MACHINES CORPORATION, Armonk, NY (US)

(21) Appl. No.: 13/553,559

(22) Filed: Jul. 19, 2012

(51) Int. Cl. H01L 23/532; H01L 23/58

(52) U.S. Cl. 257/758; 257/E23.194; 257/E23.161

(57) ABSTRACT

A semiconductor structure is provided and includes a substrate having an edge surface and a device surface with a central area, a crack stop structure disposed on the device surface and a circuit structure including components disposed on the device surface in the central area and interconnects electrically coupled to the components. The interconnects are configured to extend from the central area to the edge surface while bridging over the crack stop structure.

This invention was made with Government support under Contract No.: H98230-08-C-1496 awarded by the Maryland Project Office. The Government has certain rights in this invention.

### BACKGROUND

The present invention relates generally to semiconductor structures, and more specifically, to semiconductor structures with crack stop structures.

As complementary-metal-oxide-semiconductor (CMOS) device scaling has been reduced in recent years, chip stacking methods are being explored as options for increasing system performance. Chip stacks can increase interconnect densities and reduce interconnect lengths and are usually formed with through silicon vias (TSVs) and fine pitch microbumps between chips. This requires integration of TSVs into chip design and process flows and can also increase difficulties of adequate cooling during operation.

Alternate methods of chip stacking have included providing wire bond chip-stacks, which have limited numbers of perimeter interconnects, and forming chip cubes using “T” connections where a transfer metal level is formed, the chips are joined together into a stack and the edges are polished. In one variant, a chemically inert transfer metal is used and other metals are removed from the polished edges by wet etching. In other variants, either the same metal is used or the chip metal levels are removed during wafer processing. The polished edge is subsequently processed to pattern an additional metal layer forming T connections to the transfer metal.

### SUMMARY

According to one embodiment of the present invention, a semiconductor structure is provided and includes a substrate having an edge surface and a device surface with a central area, a crack stop structure disposed on the device surface and a circuit structure including components disposed on the device surface in the central area and interconnects electrically coupled to the components. The interconnects are configured to extend from the central area to the edge surface while bridging over the crack stop structure.

According to another embodiment of the present invention, a semiconductor structure is provided and includes a substrate having an edge surface and a device surface with a central area and a peripheral section, a crack stop structure disposed on the device surface and including a continuous structure surrounding the central area and discrete structures at the peripheral section and a circuit structure including components disposed on the device surface in the central area and interconnects electrically coupled to the components. The interconnects are configured to extend from the central area to the edge surface while bridging over the crack stop structure.

According to yet another embodiment of the present invention, a chip stack including a plurality of stacked semiconductor structures is provided. Each semiconductor structure includes a substrate having top and bottom edge surfaces and a planar surface with a central area, a crack stop structure disposed on the planar surface and a circuit structure including components disposed on the device surface in the central area and interconnects electrically coupled to the components. The interconnects are configured to extend from the central area to the top and bottom edge surfaces while bridging over the crack stop structure.

Additional features and advantages are realized through the techniques of the present invention. Other embodiments and aspects are described in detail herein and are considered a part of the claimed invention. For a better understanding, refer to the description and to the drawings.

### BRIEF DESCRIPTION OF THE SEVERAL VIEWS OF THE DRAWINGS

The forgoing and other features, and advantages of the embodiments are apparent from the following detailed description taken in conjunction with the accompanying drawings in which:

FIG. 1 is a perspective schematic view of a chip stack in accordance with embodiments;

FIG. 2 is a plan view of the chip stack of FIG. 1;

FIG. 3 is an enlarged view of a portion of the plan view of FIG. 2 illustrating a crack stop;

FIG. 4 is an enlarged view of a portion of the plan view of FIG. 2 illustrating a crack stop in accordance with alternative embodiments;

FIG. 5 is a diagram illustrating a process of forming the crack stop of FIG. 3 or FIG. 4;

FIG. 6 includes side views of the crack stop of FIG. 3 in accordance with embodiments;

FIG. 7 is a side view of the crack stop of FIG. 3 in accordance with alternative embodiments;

FIG. 8 is a side view of an interconnect in accordance with alternative embodiments;

FIG. 9 is a side view of an interconnect in accordance with alternative embodiments;

FIG. 10 is an enlarged view of a crack stop with discrete coupling structures in accordance with further embodiments; and

FIG. 11 is a plan view of a chip stack with built-in-self-test (BIST) circuitry in accordance with further embodiments.

### DETAILED DESCRIPTION

In complementary-metal-oxide (CMOS) chips using low-k dielectric materials, a perimeter crack stop serves to prevent cracks from propagating from the dicing channel at interfaces between the low-k dielectric layers. The crack stop has typically been formed by two or more continuous rings of stacked metal around the perimeter of the chip with all metal lines and via layers up to and including a last metal layer incorporated.

When copper (Cu) is used as the wiring metallurgy in the chip back end of line (BEOL) wiring layers, it is often necessary to passivate the copper and protect it from oxidization. This can be accomplished by forming a conductive adhesion and barrier layer of tantalum (Ta) and tantalum nitride (TaN) on the bottom and sides of the copper lines and using a passivating dielectric cap layer above the lines. In a BEOL wiring design, finer pitch lines and low-k dielectric layers are used adjacent to the active Si devices to interconnect them. Subsequent upper layers are used for longer distance interconnections and are progressively thicker and have progressively larger minimum pitches. Also, in the upper wiring layers, oxide based dielectric layers may be used. The cracking concern is generally with the low-k dielectric layers and not the upper oxide based dielectric layers.

The low-k dielectric layers may consist of various materials along with capping layers. In a standard CMOS process flow, a final metallization layer may be included, which is formed of an aluminum (Al) alloy, with a barrier/adhesion layer and an antireflective layer. Aluminum is generally self-passivating and forms a limited, tough, adhering oxide when exposed to air. For some applications, this final aluminum is used to form wire bond pads around the perimeter of the chip.

In a typical chip, a crack stop is designed to prevent the propagation of a crack below a certain maximum length. A crack above this length could potentially have sufficient energy to rupture the crack stop. Generally, the critical length selected is significantly greater than the distance between the crack stop and the dicing channel, which are typically about 10-20 microns apart, so there is no possibility of the crack stop failing. In certain cases, the crack stop will be offset from the dicing channel by up to 200 microns, which could result in a crack that would potentially rupture the crack stop. Where the typical chip is to be assembled in a chip stack, after the chips are stacked together and bonded to form a “brick” containing multiple modules, the top and bottom edge surfaces are ground, polished and corner crossing connections are formed. Due to assembly tolerances, the location of the active devices and crack stops relative to the polished surface in the chips varies. To account for these variations, a grind/polish uncertainty region is needed and can range in width from about 20 to 200 microns.

Aspects of the present disclosure are directed to providing electrical connections across the crack stop, which do not compromise integrity or performance of the crack stop. Further aspects are directed to preventing or impeding the formation of cracks in the grind/polish uncertainty region. To that end, structures are provided that can accommodate these disparate requirements. That is, in the grind/polish uncertainty region, strengthening structures are provided between corner crossing wires and top layers are used to pass signals over the crack stop structures.

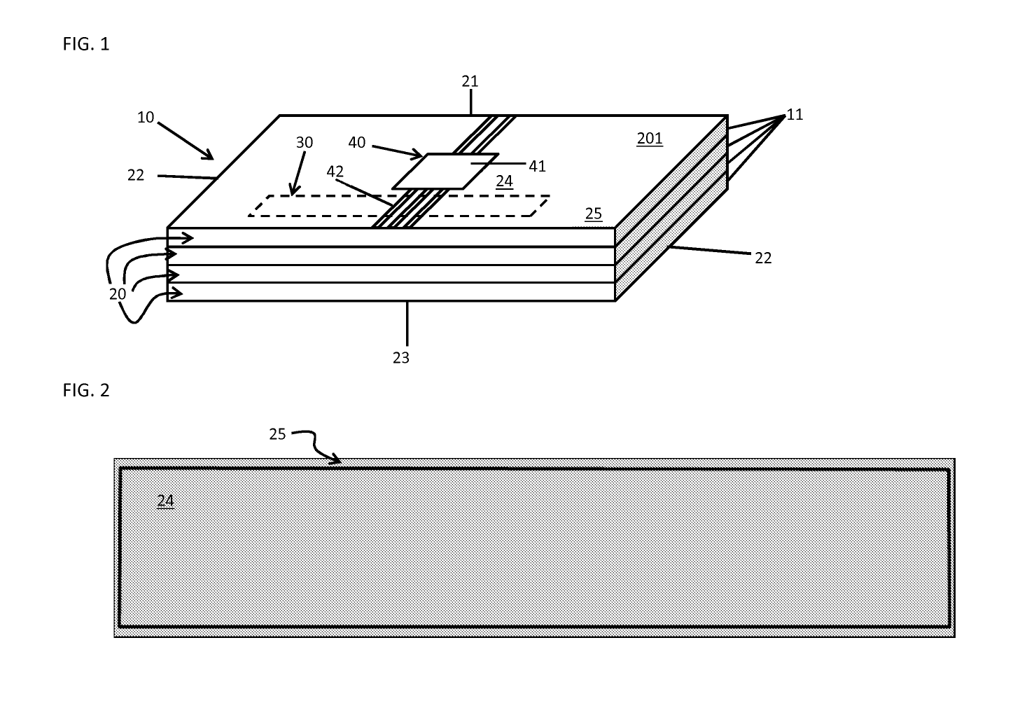

With reference to FIGS. 1 and 2, a chip stack 10 is provided. The chip stack 10 includes a plurality of stacked semiconductor structures 11. As shown, when the semiconductor structures 11 are stacked together and operably disposed in, for example, a computing device, each semiconductor structure 11 includes a substrate 20 having a top (long) edge surface 21, side (short) edge surfaces 22 and a bottom (long) edge surface 23. Each respective substrate 20 has a planar device surface 201 having two dimensions (e.g., X and Y dimensions) with a central area 24 and a peripheral section 25 defined around the central area 24. As shown in FIGS. 1 and 2, the central area 24 may be, but is not required to be, substantially rectangular. For the purposes of clarity and brevity the following description will apply to the rectangular embodiments but this is to be understood as merely exemplary.

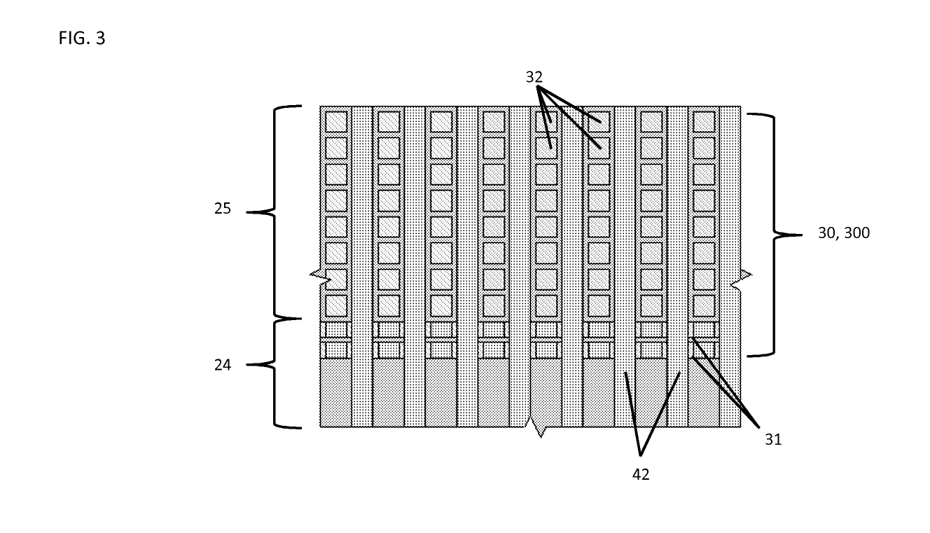

With reference to FIGS. 1-3, a crack stop structure 30 is disposed on the device surface 201 (in, e.g., the Z dimension) for each of the semiconductor structures 11. The crack stop structure 30 includes a continuous structure 31 and discrete structures 32. The continuous structure 31 is continuous in at least the long dimension of the device surface 201 and may extend around each of the four sides of the central area 24 (as shown in FIG. 3, the continuous structure 31 may actually include two or more discrete continuous structures 31). The discrete structures 32 are discontinuous in the dimensions of the device surface 201 and may be provided in at least one or both of the grind/polish uncertainty regions at the top and bottom (i.e., long) edge surfaces 21 and 23. A width of the grind/polish uncertainty regions at the top and bottom edge surfaces 21 and 23 may range from about 20-200 microns or, more specifically, from about 100-150 microns. The continuous structure 31 is thus formed to surround the central area 24 and the discrete structures 32 are formed at portions of the peripheral section 25 at one or more sides of the central area 24.

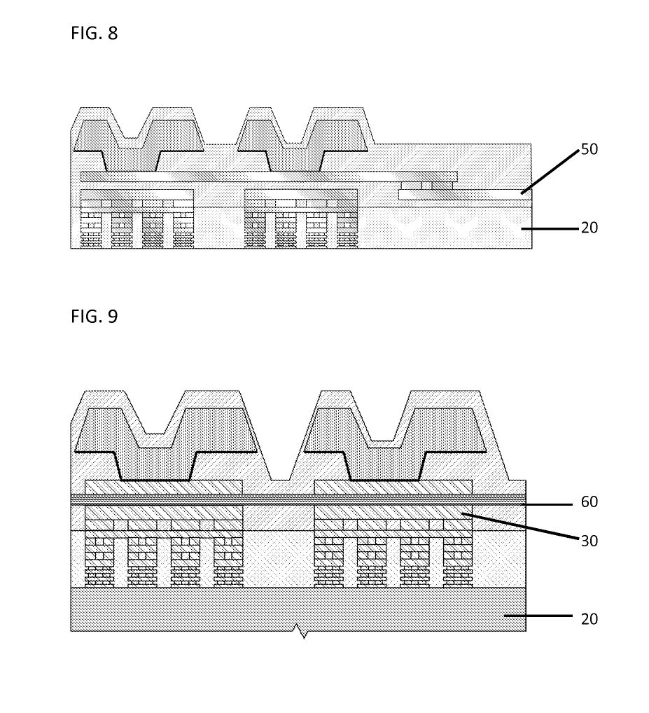

The chip stack 10 further includes a circuit structure 40 for each of the semiconductor structures 11 (see FIG. 1). Each circuit structure 40 includes components 41 that are operably disposed on the device surface 201 in the central area 24 and interconnects 42 that are electrically coupled to the components 41. The interconnects 42 are configured to extend from the central 24 area to at least one or both of the top edge surface 21 and the bottom edge surface 23 while bridging over the crack stop structure 30. The interconnects 42 may include one or more of a metallic connection, an aluminum (Al) connection, a copper (Cu) connection as in FIG. 8, an optical connection (i.e., an optical wave guide) and a Radio Frequency (RF) connection as in FIG. 9.

With reference to FIGS. 3-7, embodiments of the crack stop structure 30 are illustrated.

As shown, the continuous structure 31 and the discrete structures 32 each include BEOL layers 300 of copper (Cu) material. The interconnects 42 are provided as corner crossing wires formed of a layer of metallic (e.g., Al or Cu) material. In the portions of the peripheral section 25 at the one or more sides of the central area 24 where the discrete structures 32 are formed, the discrete structures 32 act as strengthening structures between the interconnects 42. As noted above, the discrete structures 32 each include BEOL layers 300 of copper (Cu) material and are broken up into discontinuous islands.

In an exemplary application, a case of localized passivation failure after 4Di chip stack processing could result in oxidization of the copper (Cu) in the discrete structures 32 exposed by grinding and polishing. In such a case, segmentation of the discrete structures 32 and a lack of a continuous copper path between the grind/polish surfaces and the continuous structure 31 cooperatively eliminate a risk of damage to a portion of the discrete structures 32 and the continuous structure 31 by progressive oxidization. The discrete structures 32 also reduce a risk of shorting between the interconnects 42 if there are any defects in insulation layers between surfaces of the discrete structures 32 exposed by polishing.

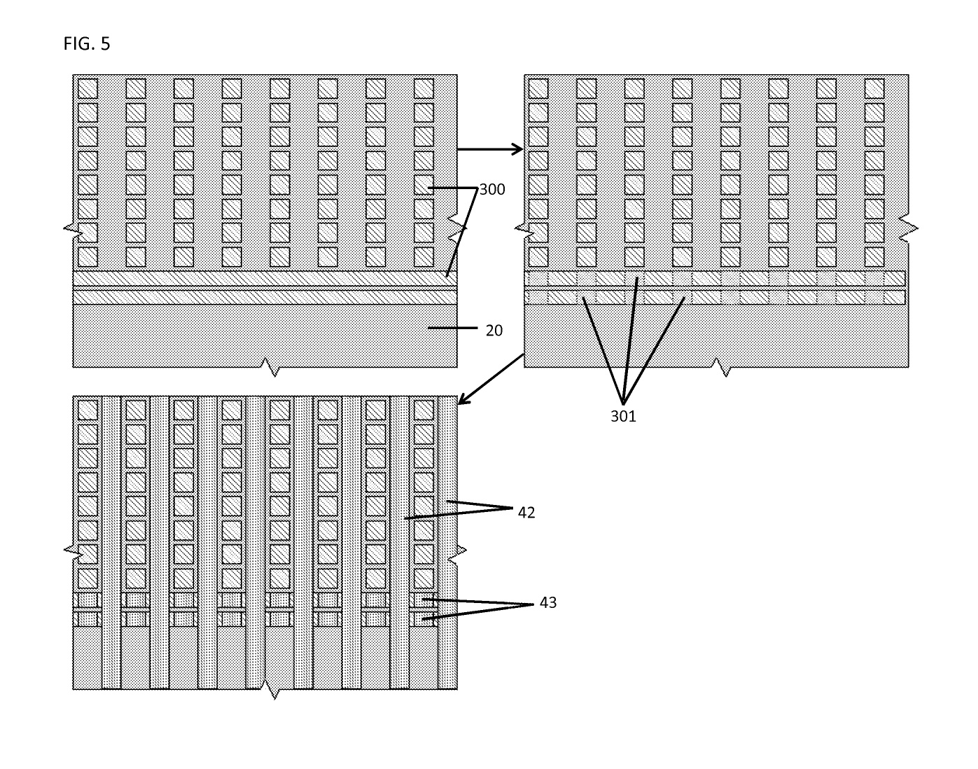

With reference to FIG. 5, a method of forming the crack stop structure 30 is diagrammed. As shown, in an initial operation, the BEOL layers 300 of copper (Cu) material are formed and passivated to take the shape of the continuous structure 31 and columns of the discrete structures 32 that are aligned between locations where the interconnects 42 will be located. A top passivation layer is then opened to form vias 301 extending to top copper layers of the continuous structure 31 between the locations where the interconnects 42 will be located. Metallic material, such as aluminum (Al), is then patterned to form the interconnects 42 as well as discrete metallic structures 43 where the vias 301 were formed. Passivation layers are deposited as a last operation.

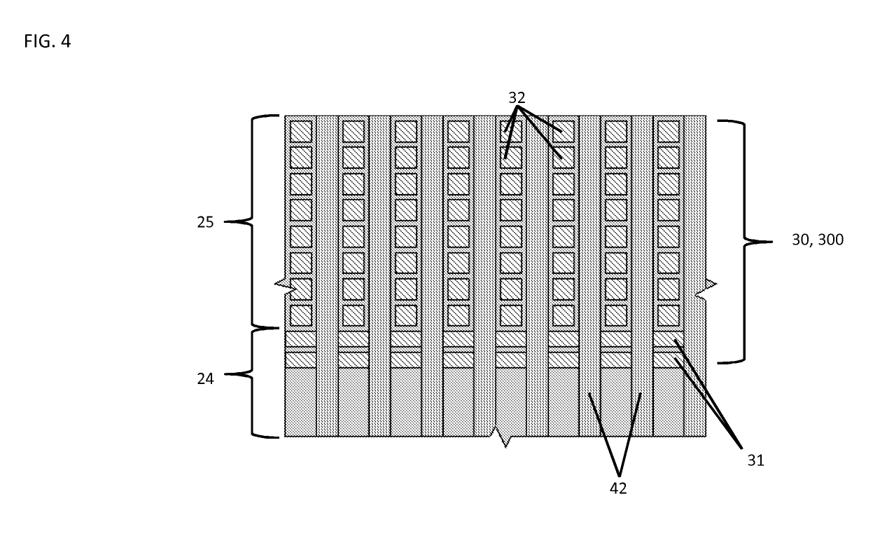

As shown in FIG. 4 and, in accordance with alternative embodiments, the formation of the vias 301 may be skipped along with the discrete metallic structures 43. In such cases, a top copper layer of the continuous structure 31 between adjacent interconnects 42 may be a top-most layer of the continuous structure 31.

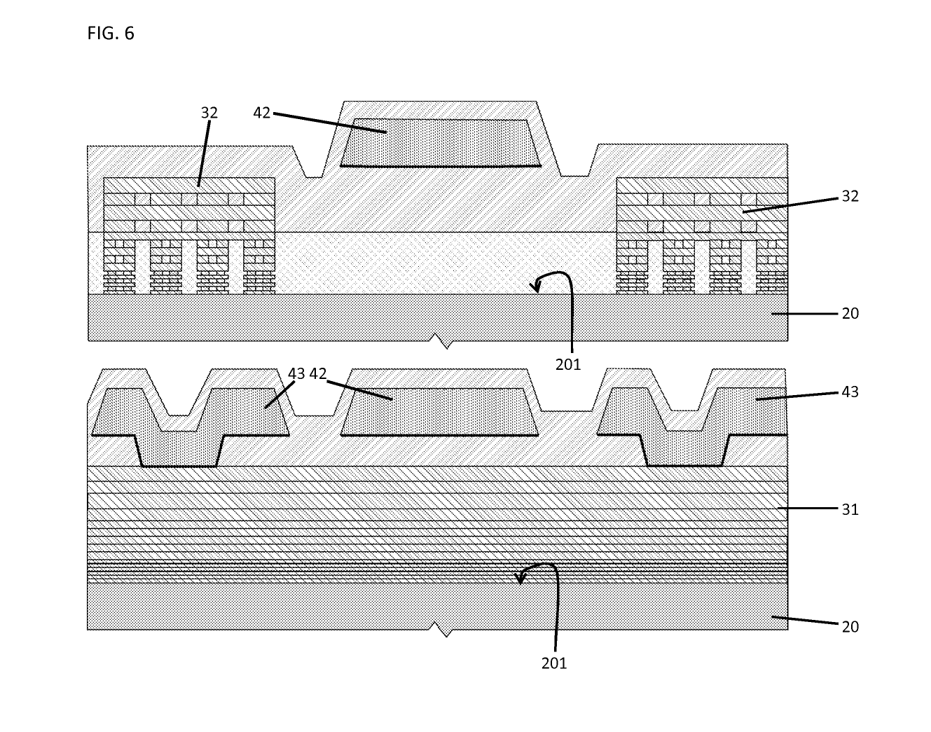

As mentioned above, when the BEOL layers 300 of copper (Cu) material are formed and passivated, the BEOL layers 300 take the shape of the continuous structure 31 and columns of the discrete structures 32 that are aligned between the locations where the interconnects 42 will be located. Similarly, when the vias 301 are formed, the vias 301 are formed between locations where the interconnects 42 are to be located. As such, with reference to FIG. 6, the interconnects 42 are electrically isolated from the continuous structure 31 of the crack stop structure 30 and no discrete structures 32 are located under the interconnects 42 in the grind/polish uncertainty region.

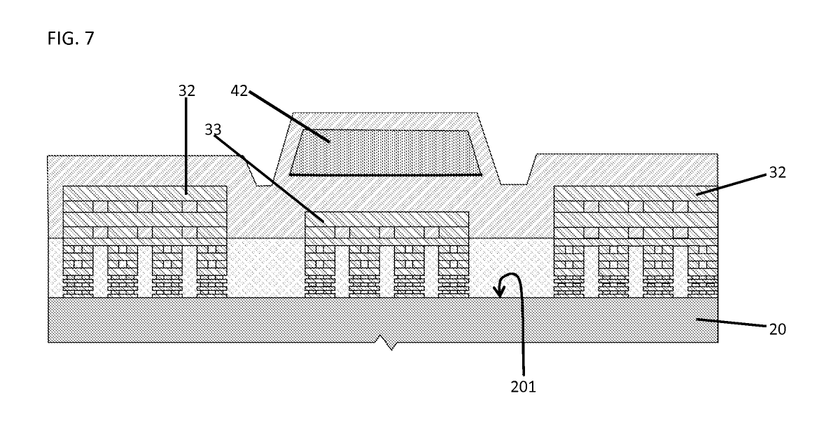

In accordance with alternative embodiments and, with reference to FIG. 7, additional discrete structures 33 may be provided. Such additional discrete structures 33 may be disposed in the grind/polish uncertainty region between the interconnects 42 and the substrate 20 and are shorter with respect to a plane of the device surface 201 than the discrete structures 32 between adjacent interconnects 42. With the embodiment shown in FIG. 6, for example, if a corner crossing pitch is 25 microns, the interconnect 42 width is 10 microns and a spacing between an edge of the discrete structures 32 and the interconnect 42 is 3 microns, the discrete structure 32 could be 9 microns wide.

With reference to FIGS. 8 and 9, alternative embodiments are illustrated in which an interconnect 42 includes upper level copper (Cu) metallurgy 50 (see FIG. 8) or an optical or electromagnetic (i.e., radio frequency (RF)) wave guide 60 (see FIG. 9). As shown in FIG. 9, the optical or electromagnetic wave guide 60 passes through the crack stop structure 30 to provide for an optical or electromagnetic interconnect 42. The optical or electromagnetic wave guide 60 may include, for example, a high index transparent core surrounded by a transparent cladding material with a lower index of refraction so that the light is confined by internal reflection. As shown in FIG. 9, the optical waveguide could be replaced with an electromagnetic wave guide 60.

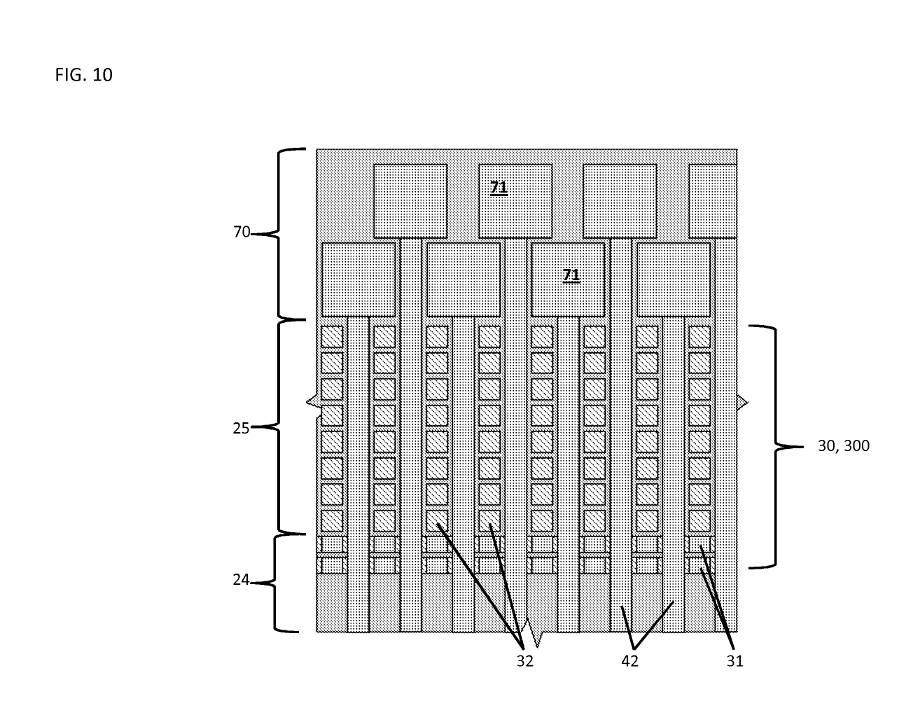

In accordance with further embodiments and, with reference to FIG. 10, additional discrete coupling structures 70 may be provided in the dicing channel outside of the crack stop structure 30 on one or more sides of the central area 24. Such discrete coupling structures 70 are connected to one or more of the interconnects 42 and are exposed on the device surface 201 to enable electrical, optical or radio frequency coupling to the interconnects 42 prior to forming a chip stack 10.

With reference to FIG. 10, and, in the particular embodiment where the interconnects 42 are formed of metallic materials, the discrete coupling structures 70 may be provided as metallic pads 71 that are patterned in one or more upper levels of wiring and formed at least in part with a wiring level that is common to that of the interconnects 42. The discrete coupling structures 70 in FIG. 10 may be formed outside the crack stop structure 30 and removed when the chip stack 10 is formed.

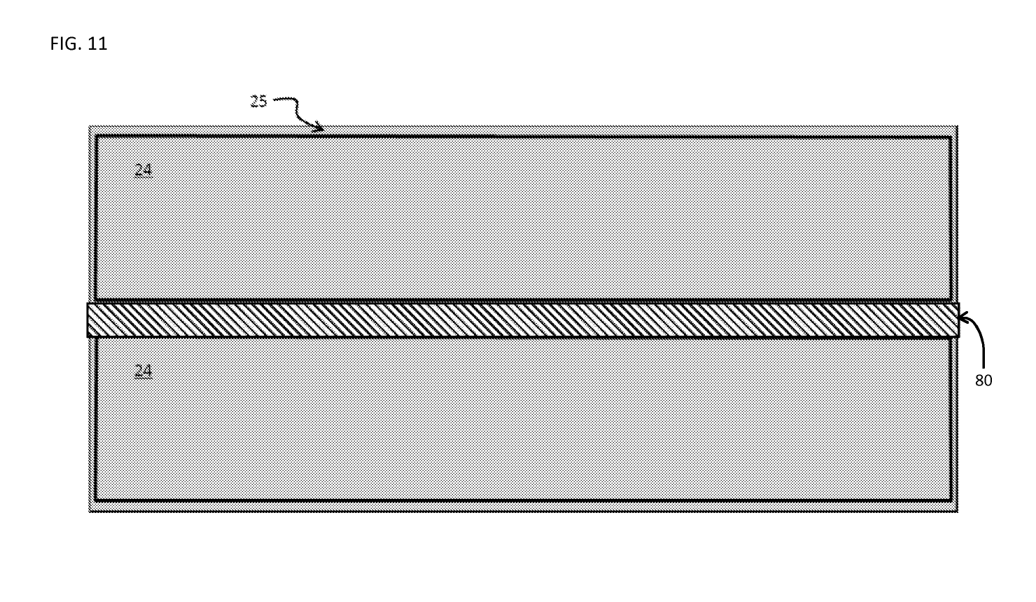

With the additional feature of being able to remove silicon areas from the design at a post wafer level test stage, many new applications are opened or available with regards to built-in-self-test (BIST) operations and/or any additional test and characterization functionality. Historically, BIST relates to circuitry placed inside of a chip area. However, with reference to FIG. 11 and, with the interconnects 42 provided as described above, BIST circuitry 80 may be placed outside of a post diced chip area or between the active portions of central area 24, as shown in FIG. 11. In fact, the BIST circuitry 80 may be shared between dies thereby having a significant savings in efficiency. With the BIST circuitry 80 on the outside of the die, the finished product will save any leakage power and also area penalties with the BIST circuitry 80 area. While the BIST circuitry 80 still incurs a chips per wafer penalty this can be reduced by the die sharing.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited. Many modifications and variations will be apparent to those of ordinary skill in the art without departing from the scope and spirit of the embodiments. The embodiments were chosen and described in order to best explain principles and practical application, and to enable others of ordinary skill in the art to understand the embodiments for various embodiments with various modifications as are suited to the particular use contemplated.

While the embodiments have been described, it will be understood that those skilled in the art, both now and in the future, may make various improvements and enhancements which fall within the scope of the claims which follow. These claims should be construed to maintain the proper protection for the embodiments first described.

1. A semiconductor structure, comprising:
a substrate having an edge surface and a device surface with a central area;
a crack stop structure disposed on the device surface; and
a circuit structure including components and interconnects, the components being disposed on the device surface in the central area such that the components are co-planar with the crack stop structure and the interconnects being electrically coupled to the components and disposed in an interconnect plane displaced from respective planes of the components and the crack stop structure,
the interconnects being configured to extend in a longitudinal direction defined along the interconnect plane from the central area to the edge surface while bridging over the plane of the crack stop structure.

2. The semiconductor structure according to claim 1, wherein the interconnects comprise one or more of a metallic connection, an aluminum connection, a copper connection, an optical connection and a Radio Frequency (RF) connection.

3. The semiconductor structure according to claim 1, wherein the crack stop structure surrounds each side of the central area.

4. The semiconductor structure according to claim 3, wherein the crack stop structure comprises discrete structures disposed at one or more sides of the central area and formed of back-end-of-line (BEOL) layers of copper material.

5. The semiconductor structure according to claim 4, wherein the device surface comprises a planar surface with two dimensions, the discrete structures being discontinuous in the two dimensions and one of the two dimensions being defined along the longitudinal direction of the interconnects and the other of the two dimensions being defined transversely with respect to the one of the two dimensions.

6. The semiconductor structure according to claim 5, further comprising one or more discrete coupling structures to which the interconnects are coupled and which are disposed outside the central area, the one or more discrete coupling structures being configured to enable electrical, optical or radio frequency connection to the interconnects.

7. A semiconductor structure, comprising:
a substrate having an edge surface and a device surface with a central area and a peripheral section;
a crack stop structure disposed on the device surface and including a continuous structure surrounding the central area and discrete structures at the peripheral section; and
a circuit structure including components and interconnects, the components being disposed such that the components are co-planar with the crack stop structure on the device surface in the central area and the interconnects being electrically coupled to the components and disposed in an interconnect plane displaced from respective planes of the components and the crack stop structure,
the interconnects being configured to extend in a longitudinal direction defined along the interconnect plane from the central area to the edge surface while bridging over the plane of the crack stop structure.

8. The semiconductor structure according to claim 7, wherein the interconnects comprise one or more of a metallic connection, an aluminum connection, a copper connection, an optical connection and a Radio Frequency (RF) connection.

9. The semiconductor structure according to claim 7, wherein the discrete structures are disposed at one or more sides of the central area and are formed of back-end-of-line (BEOL) layers of copper material.

10. The semiconductor structure according to claim 7, wherein the device surface comprises a planar surface with two dimensions, the continuous structure being continuous in at least one of the two dimensions and the discrete structures being discontinuous in the two dimensions and one of the two dimensions being defined along the longitudinal direction of the interconnects and the other of the two dimensions being defined transversely with respect to the one of the two dimensions.

11. The semiconductor structure according to claim 10, further comprising one or more discrete coupling structures to which the interconnects are coupled and which are disposed outside the central area, the one or more discrete coupling structures being configured to enable electrical, optical or radio frequency connection to the interconnects.

12. The semiconductor structure according to claim 7, wherein the continuous structure and the discrete structures each comprise layers of copper material.

13. The semiconductor structure according to claim 12, wherein the crack stop structure further comprises a discrete aluminum structure disposed on a top copper layer of the continuous structure between adjacent interconnects.

14. The semiconductor structure according to claim 12, wherein the discrete structures are disposed between adjacent interconnects.

15. The semiconductor structure according to claim 12, wherein a top copper layer of the continuous structure between adjacent interconnects is a top-most layer of the continuous structure.

16. The semiconductor structure according to claim 12, wherein additional discrete structures are disposed between interconnects and the substrate and are shorter than the discrete structures between adjacent interconnects.

17. The semiconductor structure according to claim 12, further comprising additional test and characterization circuits placed outside of the central area.

18. A chip stack including a plurality of stacked semiconductor structures, each semiconductor structure comprising:
a substrate having top and bottom edge surfaces and a planar surface with a central area;
a crack stop structure disposed on the planar surface; and
a circuit structure including components and interconnects, the components being disposed on the device surface in the central area such that the components are co-planar with the crack stop structure and the interconnects being electrically coupled to the components and disposed in an interconnect plane displaced from respective planes of the components and the crack stop structure,
the interconnects being configured to extend in a longitudinal direction defined along the interconnect plane from the central area to the top and bottom edge surfaces while bridging over the plane of the crack stop structure.

19. The chip stack according to claim 18, wherein the interconnects of each semiconductor structure comprise one or more of a metallic connection, an aluminum connection, a copper connection, an optical connection and a Radio Frequency (RF) connection.

20. The chip stack structure according to claim 18, wherein the crack stop structure of each semiconductor structure surrounds each side of the corresponding central area,
wherein the crack stop structure of each semiconductor structure comprises discrete structures disposed at one or more sides of the corresponding central area and formed of back-end-of-line (BEOL) layers of copper material, and
wherein the planar surface of each semiconductor structure has two dimensions, the corresponding discrete structures being discontinuous in the two dimensions and one of the two dimensions being defined along the longitudinal direction of the interconnects and the other of the two dimensions being defined transversely with respect to the one of the two dimensions.
